(19) United States
(12) Patent Application Publication
(10) Pub. No.: US 2022/0244635 A1
(43) Pub. Date: Aug. 4, 2022

(54) A METHOD FOR IMPRINTING MICROPATTERNS ON A SUBSTRATE OF A CHALCOGENIDE GLASS

(71) Applicants: B.G. NEGEV TECHNOLOGIES & APPLICATIONS LTD., AT BEN-GURION UNIVERSITY, Beer-Sheva (IL); RAFAEL ADVANCED DEFENSE SYSTEMS LTD., Haifa (IL)

(72) Inventors: Mark SCHVARTZMAN, Tel Aviv (IL); Dor YEHUDA, Eilat (IL); Evyatar KASSIS, Kiryat Ata (IL); Shay JOSEPH, Kiryat Motzkin (IL)

(21) Appl. No.: 17/595,848

(22) PCT Filed: May 26, 2020
(86) PCT No.: PCT/IL2020/050574

§ 371 Date: Nov. 26, 2021

Related U.S. Application Data
(60) Provisional application No. 62/853,730, filed on May 29, 2019.

(51) Int. Cl. G03F 7/00; B81C 1/00

(52) U.S. Cl. CPC G03F 7/0002; B81C 2201/0153; B81C 1/00206

(57) ABSTRACT

In a first embodiment, the invention relates to a method for nanoimprinting a pattern on a chalcogenide-glass substrate, comprising: (A) preparing a soft operational mold, the operational mold comprising an elastomeric matrix and a reinforcement, wherein the matrix is transparent to IR radiation, and the reinforcement is opaque to IR radiation, and the mold further includes a pattern to be replicated to the substrate; (B) placing the mold on a top surface of a chalcogenide-glass substrate to form a structure, and simultaneously applying (i) IR radiation to heat an area at a top surface of the substrate to a temperature T>T_{g}, where T_{g} is the glass transition temperature of chalcogenide-glass, and (ii) applying a controlled pressure on the mold to effect penetration to the top surface of the chalcogenide-glass substrate, thereby to replicate the pattern of the mold to the top surface of the substrate; and (C) separating the operational mold from the patterned substrate.

### FIELD OF THE INVENTION

The invention relates to the field of micro-imprinting. More specifically, the invention relates to a method for imprinting micropatterns on a flat or curved chalcogenide glass body.

### BACKGROUND OF THE INVENTION

A chalcogenide glass contains one or more chalcogens, such as sulfur, selenium and tellurium, but not oxygen. Chalcogenide glasses are covalently bonded materials, and may be classified as covalent network solids.

The chalcogenide glasses are attractive materials for many infrared optical applications, thanks to their high transmittance and refractive index, which can be tuned by varying the glass composition. Furthermore, its pronounced 3^{rd} order non-linearity makes it an appealing material for all-optical switching devices. The photon-induced transition between the amorphous and crystalline phases of the chalcogenide glass also makes it a promising material for memory devices and tunable photonics.

The realization of optical devices that are based on chalcogenide glasses is often technologically challenging. For example, sub-wavelength light-manipulating structures, such as diffraction gratings or waveguides, are commonly found in many optical devices. However, the formation of such structures on chalcogenide glass substrates requires fabrication approaches that are different from those applicable in conventional optical materials, such as silicon-based glasses.

Chalcogenide glasses naturally reflect up to 30% of mid-infrared light. Thus, high-end optical components (such as lenses or windows) made of these materials usually require an antireflective coating. Traditional thin-film-based antireflective coatings require use of expensive vacuum deposition technology which is hardly applicable to chalcogenide glasses due to a lack of materials with appropriate refractive index, pure adhesion of deposited films, and a mechanical stress these films generate. This type of coating often results in cracking and delamination, especially under harsh environmental conditions. An emerging alternative to thin-film based antireflective coating are sub-wavelength micro or nano-structures (hereinafter, both referred to as “micro-structures”). The micro-structures produce a highly omnidirectional and broadband antireflective effect. These micro-structures can also provide a surface with super-hydrophobicity and self-cleaning properties, that are commonly referred to as the “lotus leaf effect”. Anti-reflective and self-clearing micro-structures have been successfully demonstrated on other commonly used materials, such as silicon or glass.

The surface of chalcogenide glasses can be directly patterned by means of an electron beam or by laser writing. However, these techniques are serial, provide low-throughput patterning, and are unsuitable for scalable fabrication. Chalcogenide glasses can be thermally imprinted with a soft elastomeric stamp.

Nanoimprint is a technique which is widely used for shaping in a nano-scale (or micro-scale) surfaces of bodies, such as, optical components, electronic devices, photonic nanostructures, etc. Soft nanoimprinting is a versatile, high-throughput, and cost-effective nanolithography technique in which a nanoscale pattern is mechanically transferred onto a resist by an elastomeric mold. In view of the mechanical flexibility of soft molds, soft imprint can produce high-resolution nanostructures in UV curable polymer films deposited on substrates with unconventional geometry, such as lenses and optical fibers. However, soft imprinting has been demonstrated so far only on thin films of chalcogenide glasses, that were in turn deposited on solid substrates such as silicon. Direct surface imprint of bulk chalcogenide glasses has still been fundamentally challenging: applying high imprint pressure and temperature necessarily deforms the imprinted substrate, whereas imprinting with a reduced pressure and temperature results in incomplete pattern transfer. Moreover, many important applications of chalcogenide glasses, such as lenses, require micro-patterning of curved optical surfaces, for example, to provide antireflection, and superhydrophobic layer. However, a scalable pattering of curved surfaces of chalcogenide glasses has not been demonstrated yet.

It is an object of the present invention to provide a method for direct surface patterning of micro-structures on a chalcogenide surface.

It is another object of the invention to provide a soft nanoimprint technique for patterning chalcogenide bodies.

It is still another object of the invention to provide a soft nanoimprint technique for patterning chalcogenide bodies, which is simple, scalable, and which can be applied in a high-throughput manner.

It is still another object of the invention to provide a soft nanoimprint technique for patterning chalcogenide bodies, having curved or flat surfaces.

It is still another object of the invention to provide a soft nanoimprint technique for patterning surfaces of chalcogenide bodies, in order to obtain non-reflective and super-hydrophobic surfaces.

Other objects and advantages of the invention will become apparent as the description proceeds.

### SUMMARY OF THE INVENTION

In a first embodiment, the invention relates to a method for nanoimprinting a pattern on a chalcogenide-glass substrate, comprising: (A) preparing a soft operational mold, the operational mold comprising an elastomeric matrix and a reinforcement, wherein the matrix is transparent to IR radiation, and the reinforcement is opaque to IR radiation, and the mold further includes a pattern to be replicated to the substrate; (B) placing the mold on a top surface of a chalcogenide-glass substrate to form a structure, and simultaneously applying (i) IR radiation to heat an area at a top surface of the substrate to a temperature T>T_{g}, where T_{g} is the glass transition temperature of chalcogenide-glass, and (ii) applying a controlled pressure on the mold to effect penetration to the top surface of the chalcogenide-glass substrate, thereby to replicate the pattern of the mold to the top surface of the substrate; and (C) separating the operational mold from the patterned substrate.

In a second embodiment, the invention relates to a method for nanoimprinting a pattern on a chalcogenide-glass substrate, comprising: (A) providing said chalcogenide-glass substrate; (B) creating on a top surface of the chalcogenide-glass substrate a layer of softened chalcogenide-glass, said softened layer having a glass transition temperature T_{sg} which is lower than a respective glass transition temperature T_{g} of the rest of the substrate; (c) placing a soft operational mold which includes a patter on the top surface of the chalcogenide-glass substrate to form a structure, and simultaneously (i) heating the structure to a temperature T_{sg}<T<T_{g}, where T_{g} is the glass transition temperature of chalcogenide-glass, and (ii) applying a controlled pressure on the mold to effect penetration to the top surface of the chalcogenide-glass substrate, thereby to replicate the pattern of the mold within said softened layer; and (D) separating the operational mold from the patterned substrate.

In a third embodiment, the invention relates to a method for nanoimprinting a pattern on a chalcogenide-glass substrate, comprising: (A) preparing a soft operational mold, the operational mold comprising a pattern to be replicated to the substrate; (B) soaking the operational mold in a solvent to produce diffusion of solvent to the mold; (C) removing the operational mold from the solvent, and placing it on a top surface of the chalcogenide-glass substrate to form a structure, and simultaneously (i) heating the structure to a temperature T_{sg}<T<T_{g}, where T_{g} is the glass transition temperature of chalcogenide-glass, and T_{sg} is a glass transition temperature of the top surface of the substrate, which results to be lower than T_{g} due to diffusion with the solvent in the mold, and (ii) applying a controlled pressure on the mold to effect penetration to the top surface of the chalcogenide-glass substrate, thereby to replicate the pattern of the mold to the top surface of the substrate; and (D) separating the operational mold from the patterned substrate.

### BRIEF DESCRIPTION OF THE DRAWINGS

In the drawings:

FIGS. 1a and 1b illustrate in schematic form typical problems that are associated with prior art techniques for nanoimprint on chalcogenide-glass substrates;

FIG. 1c illustrates in schematic form a perfect nanoimprint, as is in fact obtained by the techniques of the present invention;

FIG. 2 generally illustrates a technique for a soft nanoimprint on a surface of a chalcogenide-glass body (flat or curved), according to a first embodiment of the invention;

FIG. 3 generally illustrates a technique for soft nanoimprinting on a surface of a chalcogenide-glass body, according to a second embodiment of the invention;

FIG. 4 generally illustrates a technique for a soft nanoimprint on a surface of a chalcogenide-glass body, according to a third embodiment of the invention;

FIG. 5a shows (a) an image of a carbon nanotube-PDMS composite mold and a 3D scanning of the mold surface done by AFM (Atomic Force Microscope), and (b) AFM profile of the mold pattern;

FIG. 5b shows the result of a chalcogenide-glass imprint, as performed by the invention: (a) a 3D AFM of the pattern; and (b) a profile of the imprinted pattern;

FIG. 6 shows how a BK7 glass substrate can be used to prevent a creep during the imprint procedure;

FIG. 7 shows a diffraction grating, as introduced by the process of the invention to an As₂Se₃ lens: image (a) shows the diffraction grating, as imprinted on the surface of the As2Se3 lens; images (b) and (c) respectively show a top view and 3D-AFM view of the imprinted diffraction grating;

FIG. 8 (a)-(c) show XRD spectra of bare As2Se3, spin coated film of As2Se3 without annealing, and a spin-coated As2Se3 film annealed at 155° C. for 7 hrs;

FIGS. 9a and 9b show a 3D and z-section AFM images of the stamps used in an experiment and their corresponding imprinted structures;

FIG. 10 presents a typical 2D grating with 200 nm periodicity;

FIG. 11 a shows 3D and z-section AFM of the PDMS stamp and of the imprinted As₂Se₃ moth eye structure, for both tested geometries of the diffraction grating;

FIG. 12 shows the instruments and setup that were used during experiments of the third embodiment;

FIG. 13 shows an AFM profile of the chalcogenide-glass product, as obtained by a technique according to the third embodiment;

FIG. 14a shows a SEM image of a pattern on a product, as obtained following an imprint procedure; and

FIG. 14b shows an image of a final product, upon completion of the imprint technique of the invention;

FIG. 15 shows a reflectance spectrum of a surface imprinted with antireflective structures, as compared to that of bare As2Se3 surface, as obtained by a technique according to an embodiment of the invention; and

FIG. 16 shows a superhydrophobic characteristic of a product, as produced by an imprint technique of the invention.

### DETAILED DESCRIPTION OF PREFERRED EMBODIMENTS

The invention provides three techniques for a soft nano-imprinting on a chalcogenide-glass surface of a body, which is either flat or curved. The chalcogenide-glass is characterized by both having a melting temperature (in the order of 350°), substantially lower compared to a typical silica glass, and by having a low glass-transition temperature T_{g}—in the order of 165°-180° (163° C. for GeSe₄ or 185° for As₂S₃). The chalcogenide-glass is also highly transparent to infra-red radiation, making it a very attractive material for components of optical devices.

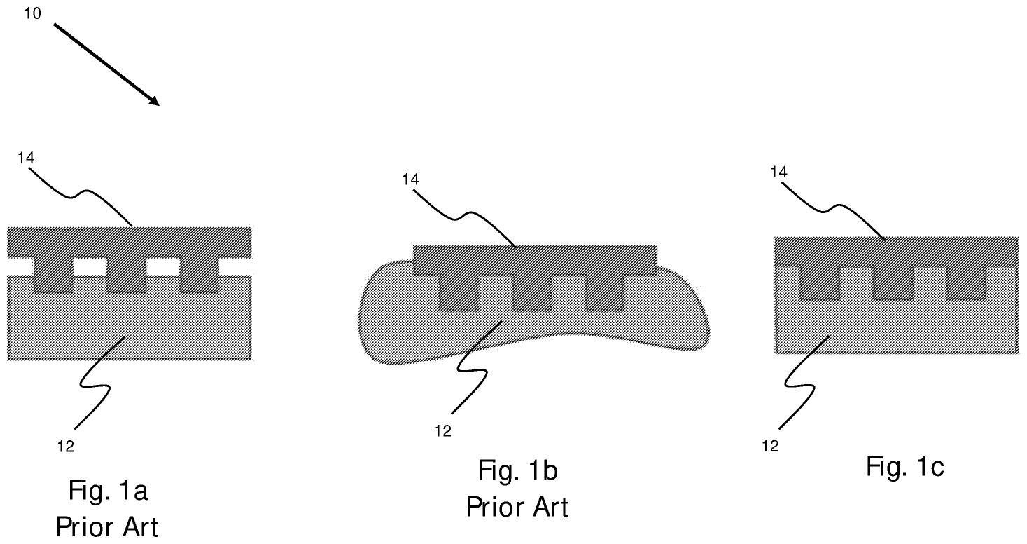

FIGS. 1a-1c illustrate typical problems that are associated with a soft nanoimprint process on a chalcogenide-glass substrate 12. The nanoimprint process utilizes a flexible soft mold 14 for the transfer of a pattern from the mold to the surface of substrate 12. Typically, a soft nanoimprint process involves a controlled heating of substrate 12 and/or the mold 14, while simultaneously applying a force on the top surface of mold 14. The prior art has not yet provided a successful technique for nanoimprinting on a substrate chalcogenide-glass, in view of some delicate characteristics of the materials involved in both the substrate and the mold. An insufficient heating of the mold-substrate structure (14 and 12 respectively) or insufficient pressure on the mold 14 yields a partial transfer of the pattern to the substrate, as shown in FIG. 1a. On the other hand, over heating of the structure or over pressure on the mold results in deformation of substrate 12, as shown in FIG. 1b. The art has not yet provided a successful soft imprint technique that assures a perfect pattern transfer (as illustrated in FIG. 1c) from mold 14 to a chalcogenide-glass substrate 12, without results of either a partial transfer (as illustrated in FIG. 1a) or deformation of the substrate (as shown in FIG. 1b).

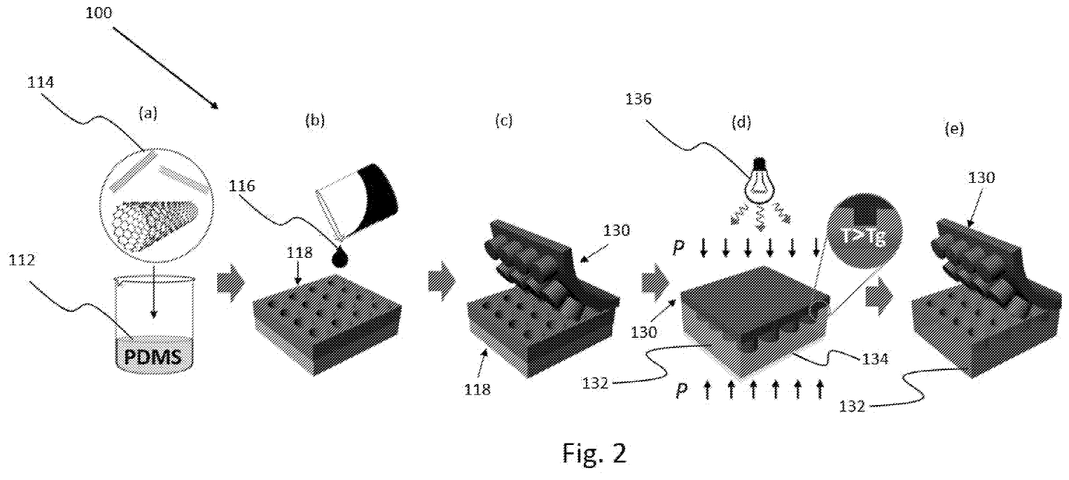

FIG. 2 generally illustrates a technique 100 for a soft nanoimprint on a surface of a chalcogenide-glass body (flat or curved), according to a first embodiment of the invention. Initially in step (a), polydimethylsiloxane 112 (PDMS, a type of soft silicon) in liquid form is mixed with carbon-nanotubes 114, to produce a mixture. While the PDMS is highly transparent to infrared light, the additive of carbon-nanotubes is an opaque material, absorbing IR light. In step (b), the PDMS-carbon-nanotubes mixture 116 is poured into a master mold 118. Master mold 118 is prepared in advance, and its pattern reflects the nanopattern which is designated for the final product. Any selected pattern may be applied to master mold 118. The patterning of the master mold may be performed by any conventional micro-fabrication technique, for example, by applying a laser beam, an electron-beam, photolithography, etc. Upon solidification of the PDMS-carbon-nanotubes mixture at the master mold, which occurs after a period of several hours at a high temperature, a soft operational mold 130 of PDMS-carbon-nanotubes is formed over the master mold 118. The soft operational mold 130 is then separated in step (c) from the master mold 118. Operational mold 130 is reinforced with a light absorbing material, such as carbon-nanotubes, and this structure is significantly important for the actual nanoimprint process. The actual nanoimprint is performed in step (d). Operational mold 130 is placed over a top surface of chalcogenide-glass body 132, and a controlled pressure P, simultaneously with IR heating 136, are applied to the structure. As noted, both the core of the operational mold 130 (which is made of PDMS) and the chalcogenide-glass body are transparent to IR. The reinforcing material of mold 130 is in fact the only IR absorbing element in the structure, and in fact the only component which can be heated by the IR radiation. This results in a very concentrated heating by the infrared radiation at the interface between the external surface of mold 130 and the top surface of the chalcogenide-glass body 132. The concentrated heat is tuned to provide a temperature above the glass transition temperature T_{g} at the interface between the mold's surface and the chalcogenide-glass body, but below the melting temperature of the chalcogenide-glass. The concentrated heating at this interface, together with the controlled pressure P, has been found to provide a successful nanoimprint process. When the mold penetrates to a sufficient depth into the chalcogenide-glass, the simultaneous applications of IR radiation and pressure P are terminated. When the structure cools down, mold 130 is separated from the chalcogenide-glass body 132, and the final product 132, with the pattern applied to its' top surface is formed. It should be noted that various alternative IR-opaque reinforcement may be applied to the PDMS mold 130, as a replacement to the carbon-nanotubes, for example, Graphene flakes, or IR absorbing nanoparticles. Moreover, various other materials that are transparent to IR, such as elastomer based on polyurethane, can be applied as a replacement to the PDMS. Optionally, a supporting layer 134 below the chalcogenide-glass body 132, made of, for example, a conventional silica glass, may be used to assist in preventing deformation. Similarly, a supporting layer (not shown) may also be used above the top surface of operational mold 130 during the imprint process (d). Experiments with the soft imprint technique of FIG. 2 have shown excellent results, as will be elaborated hereinafter.

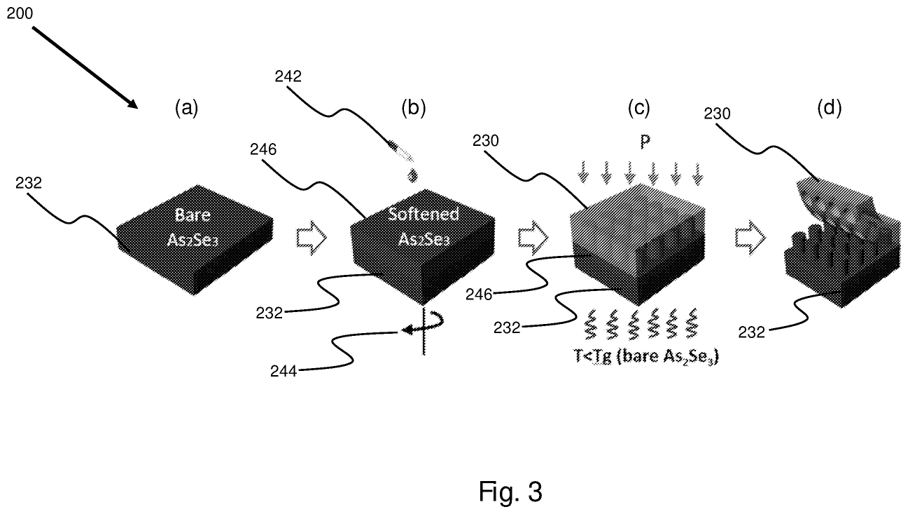

FIG. 3 generally illustrates a technique 200 for a soft nanoimprinting on a surface of a chalcogenide-glass body, according to a second embodiment of the invention. Initially in step (a), the target chalcogenide-glass body 232 is provided. The chalcogenide-glass body may be, for example, a flat or curved optical object, made for example of a bare As₂Se₃. In step (b), some chalcogenide-glass quantity, for example, As₂Se₃, is dissolved in a solvent material, for example ethylenediamine or similar. The solution may include, for example, 2%-20% of As₂Se₃ in the solvent. Next, still in (b), a spin-coating process is performed where the dissolved As₂Se₃, still in liquid form, is applied 242 to the top surface of spinning body 232 (mounted on a spinning platform—not shown). The application of the dissolved chalcogenide-glass to the top surface of the chalcogenide-glass body 232 during spinning 244, accompanied by the immediate partial evaporation of the solvent, and followed by controlled thermal treatment to evacuate more solvent (not shown), forms a softened chalcogenide-glass coating over the top surface of body 232. While the chalcogenide-glass body 232 has a certain glass transition temperature T_{g}, e.g., 165°-185° As₂Se₃, the softened coating 246 has a glass transition temperature (T_{sg}) that is significantly lower than the glass transition temperature of bulk As₂Se₃. In step (c), an operational mold 230, made of PDMS or similar, is placed on the softened coating 246 of body 232. Operational mold 230 is similar to the mold 122 of FIG. 2, however, not necessarily reinforced with a light absorbing material such as the carbon-nanotubes. Further in step (c), a soft imprint process is performed, by simultaneously applying a controlled pressure P to the top of operational mold 230, and heating to a temperature T in the range of T_{sg}<T<T_{g}, where T_{sg} is the glass transition temperature of the softened coating 246, and T_{g} is the glass transition temperature of the chalcogenide-glass body 232. For example, the heating to temperature T may apply, for example, an inductive heating from the bottom of body 232. Optionally, a membrane made of, for example, silicon elastomer, may be provided above operational mold 230, to assist with the controlled pressure P which is applied to the mold. In step (d), and following cooling of the structure, operational mold 230 is separated from body 232 to form the final product. Experiments have shown that the soft imprint technique of FIG. 3 provides excellent results, that will be elaborated hereinafter.

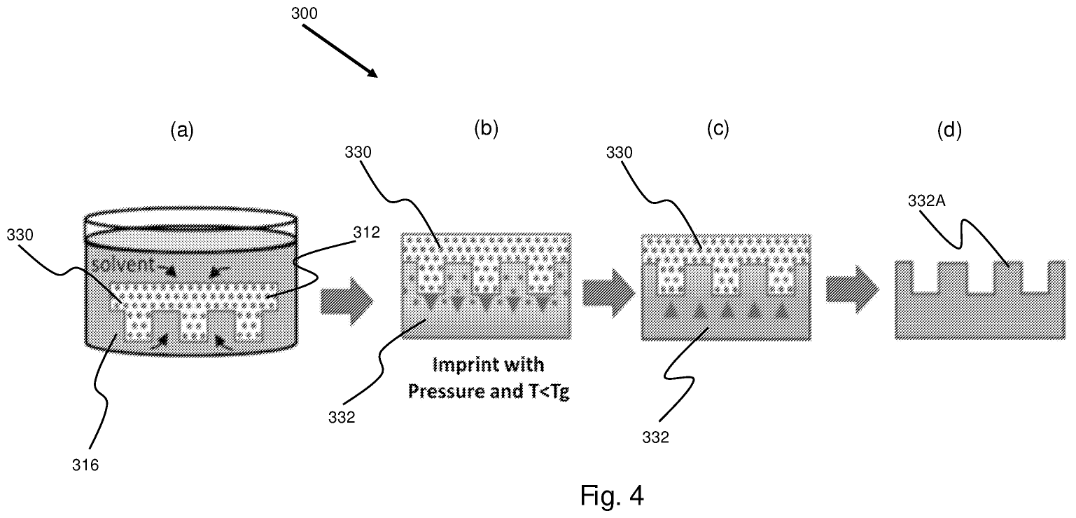

FIG. 4 generally illustrates a technique 300 for a soft nanoimprint on a surface of a chalcogenide-glass body, according to a third embodiment of the invention. In step (a), a PDMS operational mold 330, which is prepared in advance and is substantially the same mold as the operational mold 230 of FIG. 3, is soaked in a solvent 316, for example, a same ethylenediamine solvent which is used in the second technique of FIG. 3. Applicant has found that a soaking period in the order of 1 minute is in many cases sufficient. During this period, solvent 316 is absorbed within operational mold 330. In step (b), operational mold 330 is removed from solvent 316, and is placed above the top surface of a chalcogenide-glass body 332. Then, a pressure P and heat are simultaneously provided to the structure. The solvent 316 that was previously absorbed within the operational mold 330 diffuses out of the mold during the imprint, and is absorbed within a thin surface layer of chalcogenide glass substrate, and thereby softens this layer. A heat of T<T_{g} at the interface between mold 330 and body 332 is sufficient to provide a successful imprint without deformation (T_{g} is the glass transition temperature of the chalcogenide-glass body). Next, the structure is cooled down as shown in step (c), and the operational mold 330 is separated from the structure to provide a successfully imprinted body 332A as shown in step (d). It has been found that also the soft imprint technique of FIG. 4 has achieved excellent results, as will be elaborated hereinafter.

### Experiments and Further Discussion—the First Embodiment

To facilitate an effective mold heating by radiation, the inventors produced the operational mold from a composite material of polydimethylsiloxane (PDMS) with multi-wall carbon-nanotubes. The operational mold was prepared by casting the PDMS-nanotube mixture onto a photolithographically fabricated master mold. The operational mold was used to directly imprint a surface of As₂Se₃—a chalcogenide glass body, whose glass transition temperature is about 185° C. The operational mold and the chalcogenide-glass substrate were sandwiched between two transparent membranes, and then heated by infrared radiative source, while simultaneously they were pneumatically pressurized. This imprint technique, together with appropriately chosen process conditions, ensured that only a thin layer at the mold-glass interface was sufficiently heated above the As₂Se₃ glass transition point. As a result of this highly localized heating, a viscous flow of As₂Se₃ was developed at the interface between the mold and the surface of the body, whereas the rest of the glass substrate was not deformed during the imprint. A full pattern transfer from the mold to the surface of chalcogenide glass was obtained, while maintaining the glass substrate undistorted at all. The inventors verified that the composition and structure of the chalcogenide glass body were both maintained throughout the imprint process. The inventors performed a series of surface analysis tests of the imprinted product, including Raman Spectroscopy, Energy-dispersive X-ray Spectroscopy (EDS), X-Ray Photoelectron Spectroscopy (XPS), and X-Ray Diffraction. During imprint on a flat substrate, the inventors found that a complete flatness of the imprinted substrate can be assured by use of a mechanical support to its back side. The inventors produced a 2D diffraction grating, and characterized it in both reflection and transmission modes.

The inventors also successfully demonstrated an imprint of chalcogenide-glass bodies having a non-planar geometry. The inventors successfully produced a diffraction grating on a spherical lens of As₂Se₃.

The pattern that was used to demonstrate the invention consisted of a 2D diffraction grating with a periodicity of 10 μm. To fabricate soft molds with this pattern, a master mold was prepared using a photolithography technique. The inventors patterned a film of photoresist on a Si substrate, and used it directly as a 3D master mold. The inventors patterned a photoresist film whose thickness was 1.6 microns, to obtain relief features at the operational mold with 1.6 μm height.

An important component of a radiative imprint process is the radiative source. Radiative heating in a nanoimprint process requires that either the operational mold or the imprinted substrate would absorb the radiation. Notably, both As₂Se₃ (as most chalcogenide glasses) and PDMS—the material of choice for the soft imprint mold—are transparent to the wavelength range (IR) of the radiative heating source used by nanoimprint equipment. To address this constraint, and to allow effective heat absorption of the soft operative mold, the PDMS mold was reinforced with multiwall carbon-nanotubes. Carbon-nanotubes are ideal adsorbing-medium candidates, for several reasons: (i) their radius is a few-orders of magnitude smaller than the relief features of the master mold, so they can easily fill these features without distorting the produced pattern; (ii) carbon-nanotubes are mechanically flexible; and, (iii) they effectively absorb light in the visible and near IR spectra.

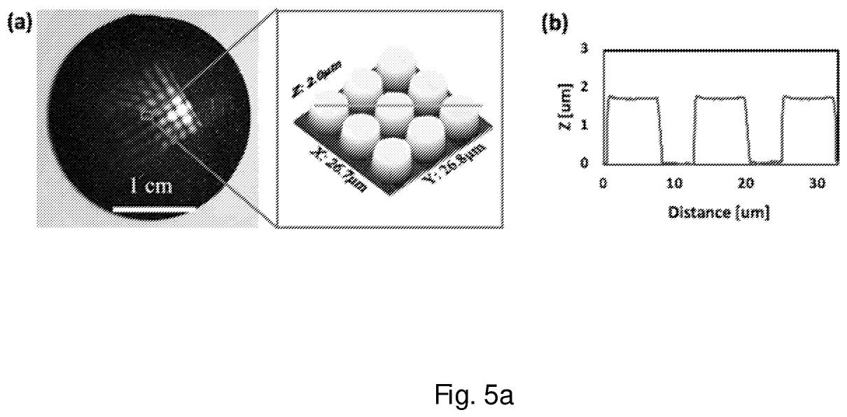

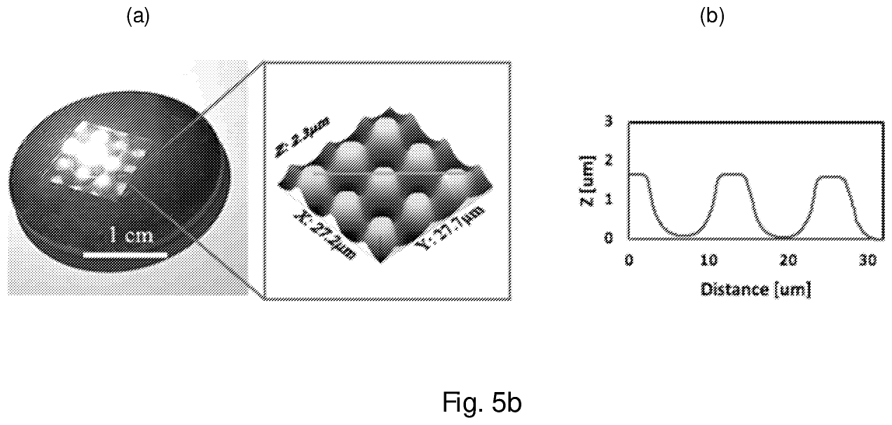

A mixture of PDMS and multiwall carbon-nanotubes was directly casted onto a master mold in the form a silicon wafer with patterned photoresist. Then, the master mold was baked. When cooled down, the operational mold was formed, and was mechanically peeled off the master mold. The dimensions of the relief features on the obtained operational mold precisely replicated the pattern at the master mold. FIG. 5a shows (a) an image of the carbon nanotube-PDMS composite mold and 3D scanning of the mold surface done by AFM (Atomic Force Microscope); and (b) AFM profile of the mold pattern. The height of the features (1.6 microns) exactly matched the thickness of the photoresist used at the master mold.

A remarkable advantage of the radiative heating in the imprint process of the first technique is that it allows fast heating

to the desired temperature, usually within a few seconds. In the setup used by the inventors, the heating source faced the back side of the operational mold. Since carbon nanotube-PDMS composite is an effective thermal conduction, it was assumed that the AS₂Se₃ surface reached the imprint temperature immediately at the beginning of the heating. The total imprint time was kept equal to 4 minutes. This imprint time was found to be sufficient to achieve full pattern transfer, but short enough to prevent deformation of the bulk of the As2Se3 substrate. Such a tight control over the imprint period enabled maintaining the original shape and dimensions of the As2Se3 substrate. The result of the chalcogenide-glass imprint is shown in FIG. 5b: (a) The imprinted As2Se3, including 3D AFM of the pattern; and (b) The profile of the imprinted pattern.

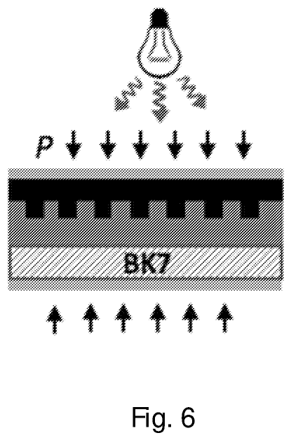

To quantitatively assess the possible impact of imprint on the global shape of the As2Se3 substrate, the inventors characterized its flatness by profilometry and 2D laser scanning. It was found that the As2Se3 developed a bow of about 150 microns, which was due to the creep that As2Se3 undergrows at the temperature and pressure used by the process. To prevent this creep, the inventors attached a flat (flatness <1 μm) BK7 glass substrate to the backside of the As2Se3 substrate (FIG. 6). The result was a near zero bow, and a small warpage (measure of localized deviation from complete flatness) compared to that of a pristine unimprinted As2Se3 substrate.

Maintaining the structure and composition of chalcogenide glasses during their imprint is very significant for their optical applications. It is known, for example, that chalcogenide glasses (such as As₂S₃) crystalize upon their imprint. As for AsₓSe₁₋ₓ glasses, their bulk-nucleation and crystallization that occurs during the thermal cycles was fundamentally investigated, and it was found to depend on the Aₛ content and the impurities present in the glass. The crystallization of a nanoimprinted chalcogenide glass is highly undesirable for optical applications, because of the high scattering loss caused by the crystalline domains. To assess whether the imprint process caused any crystallization of As₂Se₃, the inventors characterized the imprinted surface by X-ray Electron Diffraction. The measured spectrum showed a broad-peaks characteristic of a completely amorphous structure of As₂Se₃, and clearly demonstrated that the nanoimprint process of the invention did not cause crystallization.

The inventors used additional characterization techniques to assess any possible effect of the nanoimprint process on the structure, and on the composition of the As₂Se₃ final product. Those techniques have confirmed that no crystallization took place on the imprinted final product.

The inventors also characterized bare and imprinted As₂Se₃ surfaces by X-ray Photoelectron Spectroscopy (XPS), and found that in both cases the surface contained Aₛ and Sₑ in stochiometric ratio (2:3). The inventors also found a certain amount of oxygen. An XPS analyses at varying depths using Aᵣ sputtering revealed that both in the bare As₂Se₃ substrate and in the imprinted substrate, oxygen was present only down to about 20 nm depth. Since the binding energies of As and Se peaks did not vary with the sampling depth, it was concluded that the oxygen signals were originated from contaminations rather than from oxidized As and Se. Finally, a presence of silicon was seen on the imprinted As₂Se₃ surface. The binding energy of Si was found to be 103 eV, which corresponds to a known measured value for Si2p in PDMS. It was thus concluded that both the observed O and the Si signals were originated from a minor contamination caused by the contact with PDMS during the imprint process. It was also confirmed that Si contamination is present only on the surface and not deeper in the bulk of As₂Se₂, based on EDS of bare and imprinted substrates.

To demonstrate the applicability of the imprint process in the fabrication of optical devices and components, the inventors characterized the imprinted diffraction grating in two modes, reflective and transmit. Since As₂Se₃ is reflective in the visible region, the inventors used a HₑNₑ laser (632.8 nm) as a light source for characterizing the reflective diffraction. The characterization setup consisted of a HₑNₑ laser, whose beam passed through two apertures, a standard optical aperture was used to reduce the beam diameter, and another aperture was used within a black board. The board, in turn, was used to visualize a 2D diffraction pattern reflected form the imprinted As₂Se₃. The sample tilt and rotation were aligned to ensure that the beam of the 0-order diffraction returned exactly into the aperture in the board. By measuring the distances between the laser spots in the obtained diffraction pattern, it was concluded that the diffraction angles are in a good agreement with the theoretical angles that were calculated from the relation between the diffraction angle and the grating geometry: d sin θ=nλ, (n=0, ±1, ±2 . . . ). The good agreement between the calculated diffraction-angles and the diffraction-angles measured in both x and y directions confirmed that the grating geometry was faithfully reproduced from the master mold to the imprinted surface. Such a high pattern fidelity indicates that the used technique holds a significant potential for the fabrication of precision-optics-components based on chalcogenide glasses.

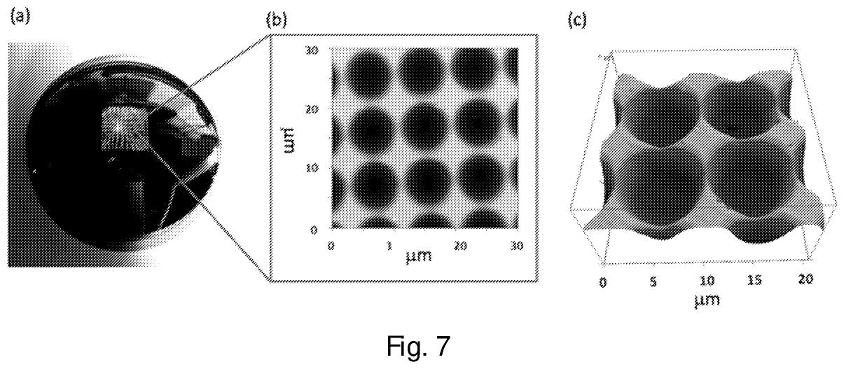

The inventors also demonstrated the applicability of the nanoimprint process of the invention to patterning of non-planar optical surfaces of chalcogenide glasses geometry. The inventors have successfully produced a diffraction grating on a lens of As₂Se₃, with a diameter of 50 mm with a radius of curvature of 43 mm. FIG. 7 shows a diffraction grating, as introduced by the process of the invention to an As₂Se₃ lens. Image (a) shows the diffraction grating, as imprinted on the surface of the As2Se3 lens; images (b) and (c) respectively show a top view and 3D-AFM view of the imprinted diffraction grating. The AFM images of this grating clearly demonstrate that the imprinted pattern faithfully replicated the geometry of the master mold. The inventors measured the grating period at the pattern center and its periphery (5 mm from the center). It was found that the period at the periphery is 6% larger than that of the master mold. It seems that this increase in the imprinted period stems from the necessity to stretch the operational mold to form a uniform and conformal contact with the curved surface of the lens. This stretch-effect can be compensated by an appropriate mold design, in which the periodicity is deliberately reduced from the center to its periphery. The inventors believe that such a technique for a direct soft imprint of a non-planar surface of chalcogenide glass has never been demonstrated before.

### Experiments Details (1^{st} Embodiment)

The production of the PDMS-nanotube composite mold (the operational mold): Multiwall Carbon-nanotubes (Cheep Tubes Inc.) were first dispersed in toluene using a probe sonicator. Simultaneously, PDMS (Sylgard 184, Dow Corning) was diluted in toluene (2:1) and was placed in an ultrasonic bath for 1 hour. The two solutions were mixed and sonicated in a probe sonicator for 1 hour. The mixture was then placed in a rotary evaporator to cause evaporation of the toluene from the solution. Finally, a curing agent was added to the PDMS-MWCNT solution and manually mixed for 10 minutes. The solution was then casted onto a master mold, degassed and baked.

The nanoimprint procedure: 2.5 cm circular substrates of As₂Se₃ were imprinted in a commercial nanoimprint tool (Nanonex NX-B200). The mold was placed on the bottom, facing the radiative source. The imprint temperature was 220° C. (which was monitored throughout the imprint process by a thermocouple, touching the membrane on the mold side). The imprint pressure was 50 psi, and the imprint time 4 minutes. The convex lens was imprinted using the same conditions as was used with the flat substrates.

Characterization of imprinted As₂Se₃: The flatness of the bare and imprinted substrates was measured by profilometry (Veeco Dektak 8), and laser profiler OLS5000. XRD was measured by use of Rigaku, D/max-2100, Cu(kα), 40 keV, 30 mA. Raman Spectroscopy was measured using Horiba LabRam HR evolution micro-Raman system, equipped with a Synapse Open Electrode CCD detector air-cooled to −60° C. The excitation source was a 532 nm laser with power on the sample of 0.05 mW. The laser was focused with an ×50 objective to a spot of about 2 μm. The measurements were taken with a 600 gmm⁻¹ grating and a 100 μm confocal microscope hole. Typical exposure time was 180 sec. XPS data were collected using an X-ray photoelectron spectrometer ESCALAB 250 ultrahigh vacuum (1*10⁻⁹ bar) apparatus with an AlK^{α} X-ray source and a monochromator. The X-ray beam size was 500 μm and survey spectra were recorded with pass energy (PE) 150 eV and high energy resolution spectra were recorded with a pass energy (PE) of 20 eV. To correct for charging effects, all spectra were calibrated relative to a carbon C is peak positioned at 284.8 eV. Processing of the XPS results was carried out using AVANTGE program.

### Experiments and Further Discussion—the 2^{nd} Embodiment

To verify the feasibility of the second embodiment, the inventors plasticized As₂Se₃. The inventors systematically studied the impact of the annealing conditions on the T_{g} of As₂Se surface layer formed from solution, and found that the T_{g} can be controllably lowered by almost 40° C. when compared to that of bulk chalcogenide-glass, without any substantial change to glass structure, composition, and optical properties. By a serial of chemical analyses, the inventors found that the controlled reduction of T_{g} scales with the amount of residual solvent, and concluded that the solvent functions as a plasticizing agent that facilitates the thermoforming of the glass, similarly to commercial plasticizers in organic polymers. The inventors harnessed this controlled plasticizing format to a surface imprint of As₂Se, with nanoscale features sized down to 20 nm, and applied this imprint approach to the fabrication of several functional microstructures including diffraction gratings and moth-eye antireflective coating for mid-infrared spectrum. The imprinted antireflective microstructure of the invention produced superhydrophobic effect—the first of its type on a surface of chalcogenide glass. The superhydrophobic effect was characterized by use of a Cassie-Baxter mechanism. The nanoimprint approach of the invention opens a route for a scalable-nanoscale surface patterning of chalcogenide glasses, and their numerous applications.

To produce As₂Se₃ substrates, the inventors mixed As and Se within a quartz ampoule, fused the mixture in vacuum, quenched in air, and molded the obtained glass to form discs of 25 mm in diameter and 2 mm in thickness. To form surface layers of plasticized As₂Se₃, either on Si substrates or on As₂Se₃ substrates, the inventors first grinded As₂Se₃ to obtain a fine powder and dissolved the powder in ethylene diamine (EDA). The inventors then applied the obtained solution onto either Si or As₂Se₃ substrates by spin-coating and prebaked the formed film for 2 hours at 80° C. The thickness of the obtained film ranged from 1 to 3 microns, depending on As₂Se₃ concentration and the spinning parameters. The prebaked films were then annealed during a period of 7 hours at different temperatures, to controllably evacuate the excess EDA from the films. All the steps were performed in an inert atmosphere inside a glove-box, to prevent oxidation of As2Se3 and formation of crystalline defects at its surface. Before the direct imprint of As₂Se₃ films on As₂Se₃ substrates, the inventors optimized the imprint parameters at which the film could be softened by heating above its T_{sg}. This was done while keeping the bulk As₂Se₃ substrate below its own T_{g} to prevent its deformation. The inventors found that the T_{sg} of the plasticized film depends of the amount of the residual solvent, and thus can be precisely tuned by the annealing conditions. To verify this, the inventors spin coated As₂Se₃ films on silicon substrates, annealed them at different temperatures, and measured their T_{sg} by nanoindentation. The inventors placed the substrates with the films on a nano-indenter stage with a controlled heating, and measured the indentation depth using a constant force rate of 1 mN/s until the force reached 10 mN, held the indenter at this force for 5 s, and unloaded the indenter with a constant unloading rate of 1 mN/s. The inventors repeated the measurements at different temperatures for each sample and assessed the T_{sg} in each case, based on the temperature at which the indentation depth increased abruptly. The inventors obtained a general trend by which T_{sg} gradually increases with the annealing temperature. The inventors obtained similar T_{sg} values for the annealing temperatures in the range of 140° C.-160° C., while the inventors believe that there are minor differences between these values. The highest T_{sg} (150° C.) was obtained for a film that was annealed at 170° C. This T_{sg} is, however, still lower than the T_{g} of a bulk As₂Se₃, which is typically about 185° C. The inventors believe that a higher T_{sg} of a solution deposited As₂Se₃ films can be obtained by annealing at a higher temperature and for a longer time, which will cause further removal of EDA and densification of As₂Se₃. Yet, in the context of a lithographic imprint of a plasticized As₂Se₃ film, it is important to keep the T_{sg} of the film below that of the substrate, thereby to enable thermal imprint of the film without deformation of the substrate. Based on the obtained data, a As₂Se₃ film with no annealing whose T_{sg} is 135° C., can be imprinted at around 150° C., which completely addresses the requirements of the invention. All the obtained films were very uniform and with no visible defects, most probably due to the fact that they were annealed in an inert atmosphere that prevented oxidation and crystallization of the As₂Se₃. These results provide a process window to yield high-quality plasticized As₂Se₃ films with precisely tuned T_{sg}, which, in turn, opens a route for a soft direct imprint of bulk As₂Se₃.

The performance of a functional structure imprinted on the surface of a chalcogenide-glass substrate depends not only on the shape of the structure, but also on the composition and properties of the imprinted material itself. To ensure that plasticized As2Se3 films have a composition and optical properties close to those of pristine As2Se3, the inventors performed a series of chemical, structural and optical characterizations. The inventors verified the absence of macroscopic crystallites by use of an optical microscope Then, the inventors performed a more detailed morphological study using X-ray Diffraction (XRD).

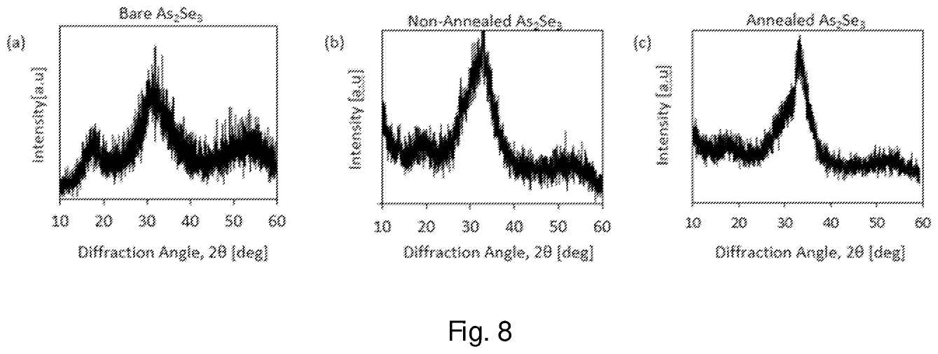

FIG. 8 (a)-(c) show XRD spectra of bare As2Se3, spin coated film of As2Se3 without annealing, and a spin-coated As2Se3 film annealed at 155° C. for 7 hrs. The three spectra are indicative of a glassy structure. The absence of any narrow peaks in the annealed film in FIG. 8 indicates complete amorphousness, namely, the obtained glass layer lacks any crystallinities that could possibly damage its optical properties. The inventors attribute the absence of crystallinities to the fact that all the processing steps were done in an inert atmosphere, which prevents oxidation of As2Se3 and, as a consequence, its crystallization.

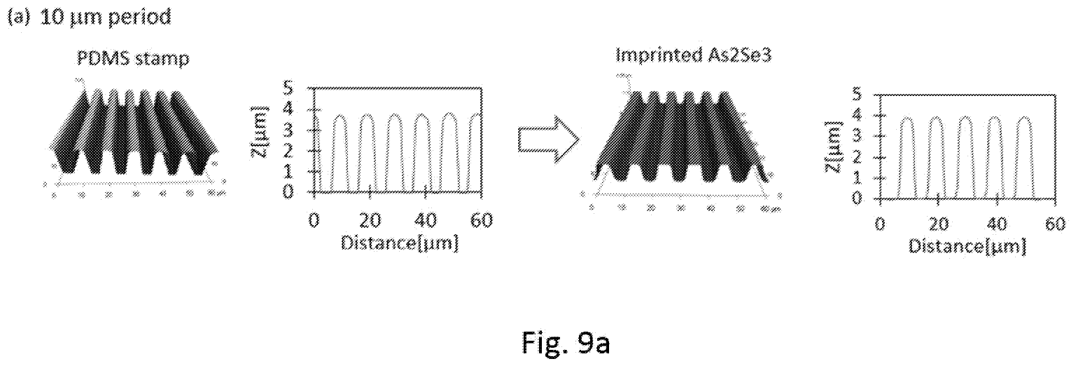

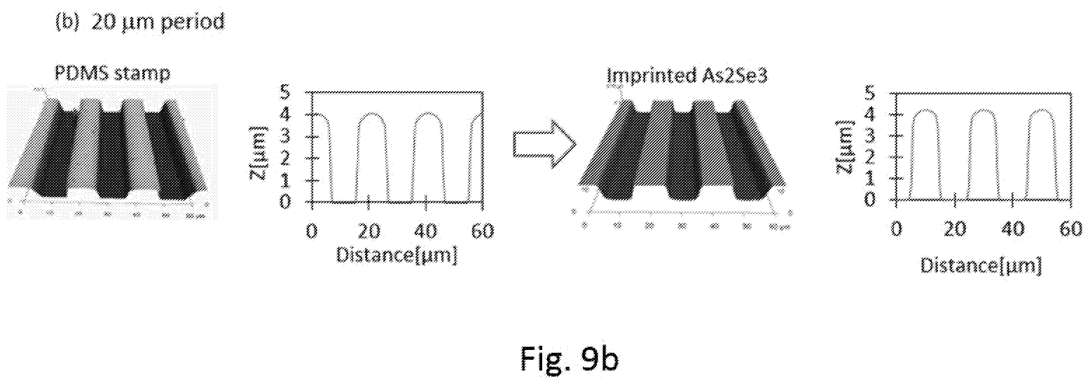

As discussed above, the inventors have demonstrated the precise tuning of the T_{sg} of plasticized chalcogenide glass films, while keeping their composition and optical properties similar to that of pristine chalcogenide glass. This enabled the production of direct and maskless surface patterning with functional microstructures via soft imprinting. As an example of such fabrication, the inventors imprinted a diffraction grating onto a plasticized surface of As₂Se₃ substrate. For this purpose, the inventors first produced a master mold by photolithography on a Si substrate followed by plasma etching and resist removal. The inventors then replicated the etched structures into hybrid hard-soft PDMS stamp, and used it to imprint a plasticized As₃Se₃ film deposited from solution onto a bulk As₂Se₃ substrate and baked at 80° C. for two hours in nitrogen atmosphere, with no further annealing. The inventors then imprinted As₃Se₃ using a custom-made imprinting tool, which is based on conductive heating of the imprinted substrate and anisotropic pneumatic pressure applied onto the attached soft stamps through a flexible membrane. The inventors used the following imprint parameters: pressure of 4 bar, time of 20 min, and temperature of 155° C. The value of the imprinting temperature was deliberately chosen between the T_{sg} of non-annealed As₂Se₃ film, previously found to be 135° C., and the T_{g} of the bulk As₂Se₃ that was equal to 185° C. The inventors imprinted two diffraction gratings with periodicities of 10 μm and 20 μm. FIGS. 9a and 9b show the 3D and z-section AFM images of the used stamps and their corresponding imprinted structures. It can be seen that the imprinted gratings exactly replicated those of the stamps in terms of periodicity and duty cycle. Furthermore, the obtained depths of the imprinted trenches fit in both cases to the height of the trenches on the stamps, thus indicating that full pattern transfers were achieved in the experiments.

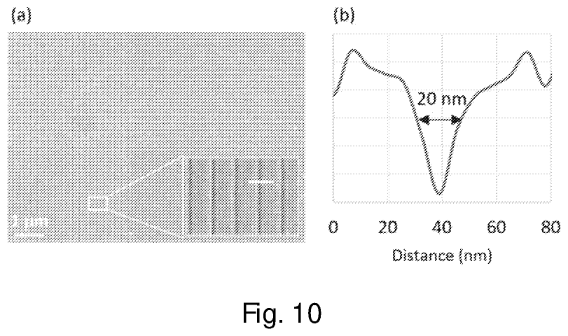

So far, the inventors demonstrated a direct imprint of a chalcogenide glass with features sized in the micron scale. However, imprinting of much smaller features, sized down to the sub-micron scale, is often required for some optical applications, such as high-performance wave-guides for near IR. To further explore the resolution that can be obtained by the nanoimprint approach of the invention, the inventors produced a master mold with a series of patterns of sub-100 nm feature size using electron-beam lithography. The inventors then replicated a soft stamp from this master mold and used it for direct thermal imprinting of As₂Se₃. FIG. 10 presents a typical 2D grating with 200 nm periodicity. Here, the exact width of the imprinted line was estimated from Full Width Half Maximum (FWHM) of the cross-section profile of the high-resolution grey scale image of the imprinted lines—(a) inset, and it was found to be equal to 20 nm (b), which precisely mirrored the linewidth in the electron-beam patterned mold. SEM images also show negligible line-edge roughness (LER), which most probably stems for the LER of the master mold. The ultra-small size of the imprinted features as well as their low LER confirm that plasticized chalcogenide glasses are greatly suitable for high-quality and high-resolution pattern transfer by direct imprinting.

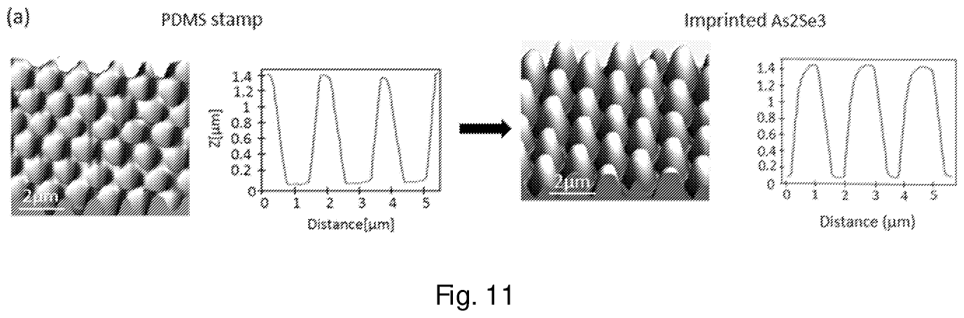

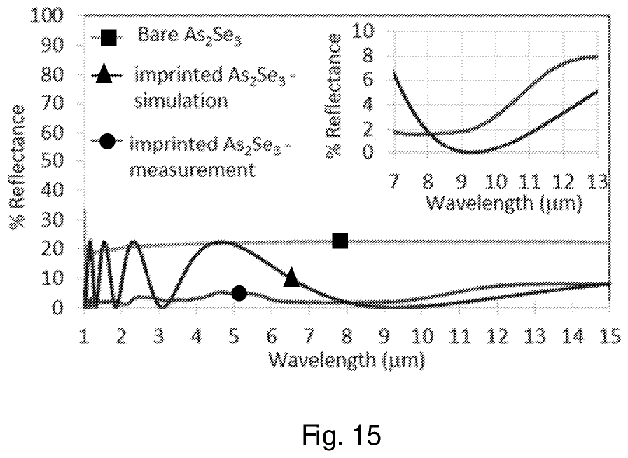

An important application of direct imprinting is the fabrication of antireflective microstructures. The inventors produced antireflective structures of periodic bumps with a periodicity of 2 μm, a duty cycle of 0.75, and a height of 1.4 μm, to provide an optimal reduction in surface reflection for a wavelength range of 8-13 μm. For this purpose, the inventors first produced a master mold by self-assembly of 2 μm polystyrene microspheres on a silicon substrate, followed by trimming of the microspheres in oxygen plasma, and etching the underlying Si through the mask formed by the microspheres. The diameter of the microspheres defined the periodicity of the moth-eye structure, and a trimming time was used to control the duty cycle. The inventors then replicated a PDMS stamp from the Si master mold and used it to imprint an As₂Se₃ substrate coated with a plasticized As₂Se₃ film, in a same manner as described above. FIG. 11 a shows 3D and z-section AFM of the PDMS stamp and of the imprinted As₂Se₃ moth eye structure, for both tested geometries of the diffraction grating. Again, the shape and height of the imprinted structures, when compared to those of the stamp, indicate full pattern transfer with very high pattern fidelity. The reflectance spectrum of the surface imprinted with antireflective structures, as compared to that of bare As2Se3 surface, is shown in FIG. 15. Importantly, the reverse side of measured substrates was grinded prior to the measurements, to minimize the effect of backside reflection. The measured spectrum is also compared to the simulated spectrum, which was calculated for a single layer antireflective coating, whose thickness is equal to the height of the antireflective microstructures, and whose effective refractive index is calculated as the sum of the As2Se3 and air indices multiplied by their volume fractions within the antireflective structure. From the comparison, it is seen that the imprinted antireflective structure produces a very low reflection in the desired wavelength range of 8-10 μm) (shown in inset), with, however, a flattened minimum, which is shifted toward lower wavelengths. This indicates that the imprinted antireflective structures have a certain height distribution, which might stem from variations in the depth of plasma-etched features in the mold used to prepare the imprinting stamp. In addition, the simulated spectrum has pronounced interference peaks at lower wavelengths, which are absent in the measured spectrum. This absence in the case of the measured spectrum is due to the dominance of optical scatterings at this wavelength range, which are not taken into account in the used simulation. However, the small peaks of the second diffraction order at ˜4.5 μm and third diffraction order at ˜2.4 μm are similar for both simulated and measured spectra.

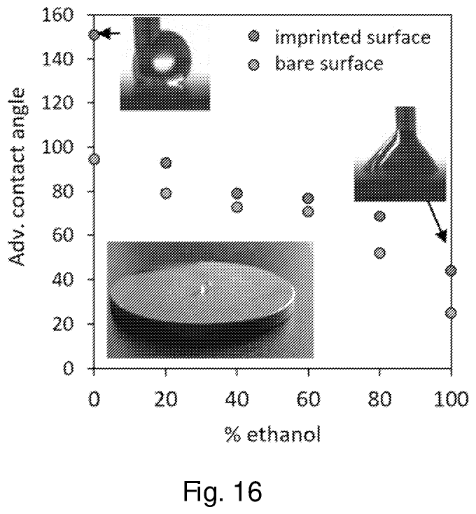

Besides the attractive antireflective properties, micro-structured surfaces possess fascinating superhydrophobic properties, and are often termed as “lotus leave effect”. This effect is particularly important for optical applications due to its self-cleaning potential: microstructures that repel water prevent surface contamination, and thus contribute to the long-term reliability and high performance of optical components. For this reason, patterned microstructures have often been produced for two purposes—antireflection and self-cleaning. However, superhydrophobic microstructures on chalcogenide glasses have not been demonstrated up to date. The inventors have used the directly imprinted moth-eye microstructures described above as a superhydrophobic coating on Aₛ2Se₃. The inventors characterized the wetting properties of imprinted chalcogenide glass by measuring advancing contact angle (θ) of water-ethanol mixtures at different ratios, and compared these to the angles on pristine flat As₂Se₃. Interestingly, for most of the water-ethanol ratios, the advancing contact angle on the patterned surface was only slightly higher than that on the flat surface. However, the contact angle of pure water on the micropatterned surface was 150°, compared to 95° on the bare surface, indicating a pronounced superhydrophobic behavior of the imprinted moth-eye pattern. The results are shown in FIG. 16.

### Experiments Details (2^{nd} Embodiment)

Preparation of plasticized As2Se3 layer: Bulk As₂Se₃ chalcogenide glass was grinded into a powder and mixed with EDA in a 2:3 mass ratio. The mixture was stirred at 80° c. for 12 hours until complete dissolution. After transfer to a glove box with Nitrogen atmosphere. The solution was spin coated either on Si or As₂Se₃ substrates, followed by soft baking at 80° c. for 2 hours. Spinning at 1000 rpm for 15 s produced a film thickness of about 2.5 μm.

Compositional, structural and mechanical characterizations of plasticized As₂Se₃ layer: XRD spectra were measured using Rigaku Spectrometer, D/max-2100, Cu(kα) source, Pass energy of 40 keV. XPS data were collected using an X-ray photoelectron spectrometer ESCALAB 250 ultrahigh vacuum (1×10⁻⁹ bar) apparatus with an Al (K^{α}) X-ray source and a monochromator. The X-ray beam size was 500 μm and survey spectra were recorded with pass energy (PE) 150 eV and high energy resolution spectra were recorded with a pass energy (PE) 20 eV. To correct for charging effects, all spectra were calibrated relative to a carbon C is peak positioned at 284.8 eV. Processing of the XPS results was carried out using AVANTAGE software. EDS measurements were performed using a scanning electron microscope fitted with EDS detector with 15 kV for 1 μm depth. A nano-indenter (MFP, Asylum Research) was used for T_{g} measurement of the annealed thin layers. For each measurement, the samples were heated up by 10° C. steps, from 130° C. to 170° C., and the indentation was carried out under a constant load of 10 mN for 5 sec. Force Indentation curves were plotted for each measurement.

Optical measurement of As₂Se₃ plasticized layers: Refractive index of the As₂Se₃ plasticized layers was measured using a Woollam IR VASE spectroscopic ellipsometer. Data were collected in the 2-40 μm range. The fitting was performed using the WVASE software. The As₂Se₃ film was assumed to be isotropic, and a non-absorbing Cauchy model was fitted in the 2-13 μm range. The reflection measurements of the As₂Se₃ films were obtained using a Perkin Elmer Frontier optics FTIR spectrometer using a 8° reflection accessory and a Ge wedge for reference. Reflection spectra of the antireflection subwavelength structures were simulated used the OPTILAYER thin films software.

Fabrication of imprint stamps: First, masters for the stamp cast were prepared. For the diffraction grating, the master was prepared using photolithography of Az2020 negative resist on silicon substrate, followed by electron-beam evaporation of Ni (100 nm), lift-off in hot acetone, Si dry etching in SF₆/C₄F₈ plasma (36 sccm SF6, 15 sccm C2H4, RF=15 W, LF=250 W, 25 min) though the Nickel mask, and NI strip using wet Ni etch (piranha solution). The master with antireflective and superhydrophobic pattern was prepared by colloidal lithography using polystyrene microspheres of 2 μm diameter in a Langmuir-Blodgett trough. Then, the microsphere diameter was reduced to 1.5 μm by dry etching in O₂ plasma (100 sccm O₂, RF=15_{W}, LF=200_{W}, 30 sec). The microsphere pattern was transferred to Si by dry etch as described above, and the remaining microspheres were removed by sonication in hot chlorobenzene. The master mold with nanometric features was fabricated by electron beam lithography (Raith eLine) using PMMA as positive resist. No pattern transfer to Si was done in this case, and patterned PMMA was directly used for the replication of the soft stamp. Hybrid soft stamps were replicated from the fabricated masters using previously reported protocol.

Direct thermal imprinting: Imprint was done in a custom-built tool (FIG. S1). A plasticized As₂Se₃ surface was first brought in contact with a soft stamp, the two were then placed between two silicone elastomeric membranes, and positioned onto heating plate inside the pressure chamber. The chamber was vacuumed to prevent the formation of air bubbles and the subsequent oxidation of the imprinted surface. Then, the substrate was heated to 155° C., and a pressure of 4 bars was applied for 20 minutes, followed by gradual cooling at room temperature. The imprinted patterns were characterized by SEM and AFM. The flatness of imprinted substrate was characterized by ZYGO Verifire (λ=0.63 μm).

### Experiments and Further Discussion—the 3^{rd} Embodiment

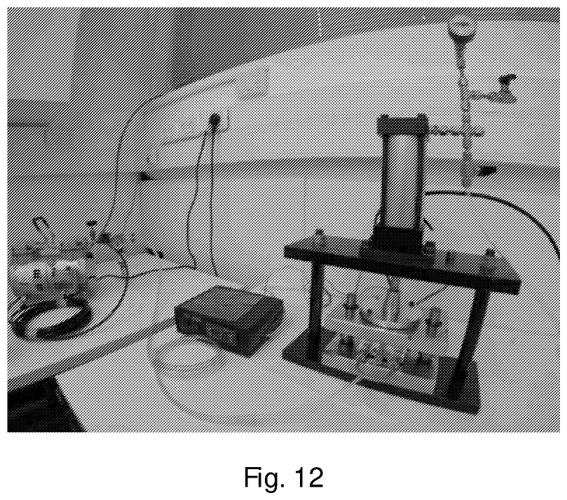

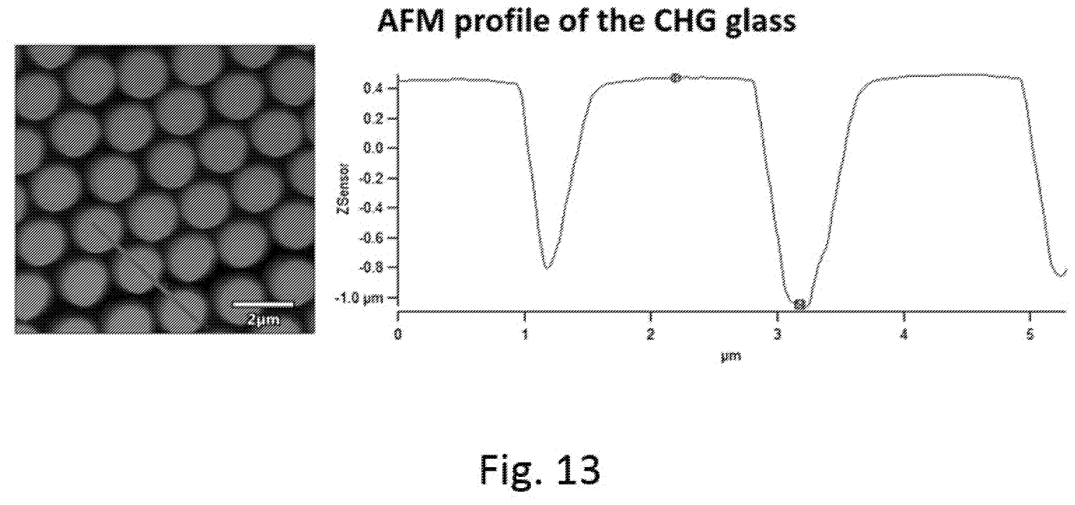

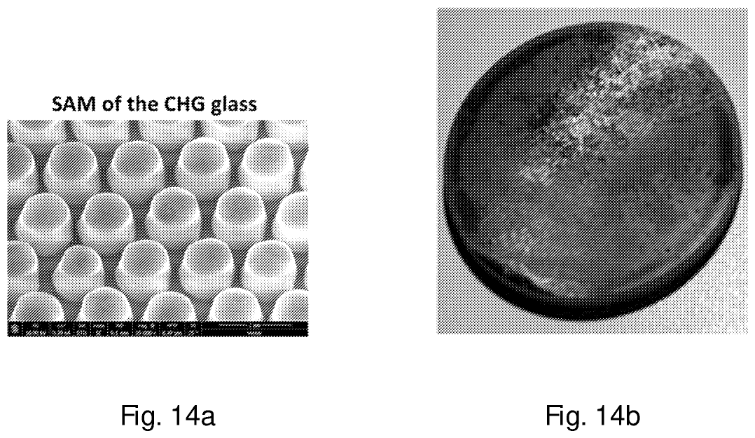

A PDMS mold was prepared substantially according to the procedure as discussed with respect to mold 230 of FIG. 3. The mold was soaked in an ethylenediamine solvent for 50 sec. During the soaking period, solvent was absorbed in the mold surface. Next, the mold was removed from the solvent, and was used for imprinting on a curved substrate of chalcogenide-glass, where the imprint temperature was T<T_{g} (T_{g} is the chalcogenide-glass transition temperature), more precisely, the temperature T was 165° (lower than T_{g}). The imprint duration was 30 minutes, and the pressure was 4 bar. The imprint process has perfectly transferred the pattern from the mold to the substrate. FIG. 14a shows a SEM image of the pattern on the product, while FIG. 14b shows an image of the final product, upon completion of the imprint technique of the invention. FIG. 12 shows the instruments and setup that was used during experiments of the third embodiment. FIG. 13 shows an AFM profile of the chalcogenide-glass product, as obtained by a technique according to the third embodiment.

1. A method for nanoimprinting a pattern on a chalcogenide-glass substrate, comprising:
preparing a soft operational mold, the operational mold comprising an elastomeric matrix and a reinforcement, wherein the matrix is transparent to IR radiation, and the reinforcement is opaque to IR radiation, and the mold further includes a pattern to be replicated to the substrate;
placing the mold on a top surface of a chalcogenide-glass substrate to form a structure, and simultaneously applying (i) IR radiation to heat an area at a top surface of the substrate to a temperature T>T_{g}, where T_{g} is the glass transition temperature of chalcogenide-glass, and (ii) applying a controlled pressure on the mold to effect penetration to the top surface of the chalcogenide-glass substrate, thereby to replicate the pattern of the mold to the top surface of the substrate; and
separating the operational mold from the patterned substrate.

2. The method of claim 1, wherein the matrix of the operational mold is made of PDMS.

3. The method of claim 1, wherein the reinforcement of the operational mold is made of carbon-nanotubes.

4. The method of claim 1, wherein the matrix of the operational mold is made of PDMS, and the reinforcement of the operational mold is made of carbon-nanotubes.

5. The method of claim 1, wherein the operational mold is prepared by:
preparing a mixture of matrix material and the reinforcement material in liquid form;
pouring the mixture on top of a master mold, and waiting for solidification; and
upon solidification, separating the operational mold from the master mold.

6. The method of claim 5, wherein the matrix material of the operational mold is PDMS, and the reinforcement material of the operational mold is carbon-nanotubes, and wherein the proportion between said materials is 2-20% of carbon nanotubes relative to the PDMS by weight.

7. The method of claim 1 wherein the imprinted pattern is anti-reflective.

8. The method of claim 1 wherein the imprinted pattern is super-hydrophobic.

9. A method for nanoimprinting a pattern on a chalcogenide-glass substrate, comprising:
providing said chalcogenide-glass substrate;
creating on a top surface of the chalcogenide-glass substrate a layer of softened chalcogenide-glass, said softened layer having a glass transition temperature T_{sg} which is lower than a respective glass transition temperature T_{g} of the rest of the substrate;
placing a soft operational mold which includes a patter on the top surface of the chalcogenide-glass substrate to form a structure, and simultaneously (i) heating the structure to a temperature T_{sg}<T<T_{g}, where T_{g} is the glass transition temperature of chalcogenide-glass, and (ii) applying a controlled pressure on the mold to effect penetration to the top surface of the chalcogenide-glass substrate, thereby to replicate the pattern of the mold within said softened layer; and
separating the operational mold from the patterned substrate.

10. The method of claim 9, wherein the creation of the layer of softened chalcogenide-glass layer is made by pouring a solvent on the top surface of the chalcogenide-glass substrate.

11. The method of claim 9, wherein the creation of the layer of softened chalcogenide-glass is made by pouring a solvent on the top surface of the chalcogenide-glass substrate, simultaneously with a spinning of the substrate.

12. The method of claim 9 wherein the solvent is selected from: ethylenediamine, or another organic liquid which is capable of dissolving chalcogenide-glass.

13. The method of claim 9, wherein the operational mold is made of PDMS.

14. The method of claim 9, wherein the heat which is provided to the structure is a conduction heat.

15. The method of claim 1 wherein the imprinted pattern is anti-reflective.

16. The method of claim 1 wherein the imprinted pattern is super-hydrophobic.

17. A method for nanoimprinting a pattern on a chalcogenide-glass substrate, comprising:
preparing a soft operational mold, the operational mold comprising a pattern to be replicated to the substrate;
soaking the operational mold in a solvent to produce diffusion of solvent to the mold;
removing the operational mold from the solvent, and placing it on a top surface of the chalcogenide-glass substrate to form a structure, and simultaneously (i) heating the structure to a temperature T_{sg}<T<T_{g}, where T_{g} is the glass transition temperature of chalcogenide-glass, and T_{sg} is a glass transition temperature of the top surface of the substrate, which results to be lower than T_{g} due to diffusion with the solvent in the mold, and (ii) applying a controlled pressure on the mold to effect penetration to the top surface of the chalcogenide-glass substrate, thereby to replicate the pattern of the mold to the top surface of the substrate; and
separating the operational mold from the patterned substrate.

18. method of claim 17, wherein the operational mold is made of PDMS.

19. The method of claim 17, wherein the solvent is selected from: ethylenediamine or another organic liquid which is capable of dissolving chalcogenide-glass.

20. The method of claim 17, wherein the heat which is provided to the structure is a conduction heat.

21. The method of claim 17 wherein the imprinted pattern is anti-reflective.

22. The method of claim 17 wherein the imprinted pattern is super-hydrophobic.
